(19) United States
(12) Patent Application Publication
(10) Pub. No.: US 2021/0104535 A1
(43) Pub. Date: Apr. 8, 2021

(54) MEMORY DEVICE WITH CONFINED CHARGE STORAGE STRUCTURE AND METHOD FOR MANUFACTURING THE SAME

(71) Applicant: MACRONIX INTERNATIONAL CO., LTD., Hsinchu (TW)

(72) Inventors: I-Chen YANG, Miaoli County (TW); Yao-Wen CHANG, Zhubei City (TW); Guan-Wei WU, Zhubei City (TW)

(21) Appl. No.: 16/591,667

(22) Filed: Oct. 3, 2019

(51) Int. Cl. H01L 27/11582; H01L 29/423; H01L 21/02; H01L 21/311; H01L 21/28; H01L 29/66

(52) U.S. Cl. CPC H01L 27/11582; H01L 29/4234; H01L 21/0217; H01L 21/02164; H01L 29/40117; H01L 21/02636; H01L 29/66545; H01L 21/31111

(57) ABSTRACT

A memory device includes a semiconductor substrate, a stack, a charge storage structure, a blocking layer, a tunneling layer, and a channel layer. The stack is disposed on a principle surface of the semiconductor substrate and includes alternately arranged conductive layers and insulating layers. The charge storage structure includes bent storage structures or discrete storage segments. Each bent storage structure or each discrete storage segment is substantially aligned with a corresponding one of the conductive layers in a direction parallel to the principle surface. The blocking layer is at least partially interposed between the conductive layers and the bent storage structures or between the conductive layers and the discrete storage segments. The tunneling layer is disposed on the bent storage structures or the discrete storage segments. The channel layer is disposed on the tunneling layer.

### BACKGROUND

### Technical Field

The present disclosure relates to a semiconductor structure and a method for manufacturing the same. More particularly, the present disclosure relates to memory devices having confined carrier storage structures and methods for manufacturing the memory devices.

### Description of Related Art

The semiconductor integrated circuit (IC) industry has experienced rapid growth. Technological progress in IC manufacture has produced several generations of ICs, and each generation fabricates smaller and more complex circuits than the previous generation. Several advanced techniques have been developed to implement smaller feature sizes, and these techniques are employed in the manufacturing of the storage devices such as flash memory devices. However, the cell structures of the memory and the manufacturing processes have not been entirely satisfactory in all respects. For example, the charges in storage layer have possibility to move to neighboring cells. Accordingly, one of the aspects of the present disclosure is to provide a solution to resolve the related issues.

### SUMMARY

On aspect of the present disclosure is to provide a memory device. The memory device comprises a semiconductor substrate, a stack, a charge storage structure, a blocking layer, a tunneling layer, and a channel layer. The semiconductor substrate has a principle surface. The stack is disposed on the principle surface of the semiconductor substrate and comprises alternately arranged conductive layers and insulating layers. The charge storage structure comprises a plurality of bent storage structures or discrete storage segments, the bent storage structures or the discrete storage segments being opposite to sidewalls of the conductive layers, wherein each bent storage structure or each discrete storage segment is substantially aligned with a corresponding one of the conductive layers in a direction parallel to the principle surface. The blocking layer is at least partially interposed between the conductive layers and the bent storage structures or between the conductive layers and the discrete storage segments. The tunneling layer is disposed on the bent storage structures or the discrete storage segments. The channel layer is disposed on the tunneling layer.

In some embodiments of the memory device, the charge storage structure comprises the bent storage structures, and the sidewalls of the conductive layers are recessed relative to sidewalls of the insulating layers to define a plurality of recesses, in which the bent storage structures are accommodated therein.

In some embodiments of the memory device, the charge storage structure further comprises a plurality of connecting portions each interconnected between adjacent ones of the bent storage structures.

In some embodiments of the memory device, the blocking layer and the tunneling layer are conformal with the charge storage structure.

In some embodiments of the memory device, the charge storage structure comprises the bent storage structures, and sidewalls of the insulating layers are recessed relative to the sidewalls of the conductive layers to define a plurality of recesses. The charge storage structure further comprises a plurality of connecting portions each interconnected between adjacent ones of the bent storage structures, and the connecting portions are accommodated in the recesses.

In some embodiments of the memory device, the blocking layer is conformal with the charge storage structure, whereas the tunneling layer is not conformal with the charge storage structure.

In some embodiments of the memory device, each bent storage structure comprises a vertical portion and two horizontal portions extending from opposite sides of the vertical portion towards the corresponding one of the conductive layers.

In some embodiments of the memory device, the charge storage structure comprises the discrete storage segments, and the sidewalls of the conductive layers are recessed relative to sidewalls of the insulating layers to define a plurality of recesses, in which the discrete storage segments are accommodated.

In some embodiments of the memory device, the discrete storage segments have sidewalls substantially flush with the sidewalls of the insulating layers, and each of the discrete storage segments has a height greater than a thickness of each of the conductive layers.

In some embodiments of the memory device, the charge storage structure comprises the discrete storage segments, and the sidewalls of the conductive layers are recessed relative to sidewalls of the insulating layers to define a plurality of recesses accommodating the discrete storage segments. Portions of the tunneling layer and the channel layer are located in the recesses.

In some embodiments of the memory device, the charge storage structure comprises the discrete storage segments, and each of the discrete storage segments comprises a vertical portion facing the sidewall of the corresponding one of the conductive layers and two flanges extending from the vertical portion towards the corresponding one of the conductive layers.

Another aspect of the present disclosure is to provide a method for manufacturing a memory device. The method comprises the following steps: forming a stack comprising alternately arranged selective function layers and insulating layers, the selective function layers and insulating layers having respective sidewalls; recessing the sidewalls of the selective function layers or the sidewalls of the insulating layers to form recesses; sequentially forming a blocking layer and a charge storage layer overlying the sidewalls of the selective function layers and the sidewalls of the insulating layers, wherein the blocking layer and the charge storage layer partially fill the recesses, thereby forming remaining spaces in the recesses; forming a tunneling layer on the charge storage layer; and forming a semiconductor layer on the tunneling layer.

In some embodiments of the method, recessing the sidewalls of the selective function layers or the sidewalls of the insulating layers comprises etching the sidewalls of the selective function layers to form the recesses, wherein forming the semiconductor layer comprises fully filling the remaining spaces with the semiconductor layer such that the semiconductor layer has corners in the remaining spaces.

In some embodiments of the method, further comprises replacing the selective function layers with conductive layers.

In some embodiments of the method, recessing the sidewalls of the selective function layers or the sidewalls of the insulating layers comprises etching the sidewalls of the insulating layers to form the recesses.

In some embodiments of the method, prior to forming the tunneling layer, further comprises: forming a dielectric layer covering the charge storage layer and fully filling the remaining spaces; and removing an extra portion of the dielectric layer to expose portions of the charge storage layer.

Another aspect of the present disclosure is to provide another method for manufacturing a memory device. The method comprises the steps of: forming a stack comprising alternately arranged sacrificial layers and insulating layers, the selective function layers and insulating layers having respective sidewalls; recessing the sidewalls of the sacrificial layers or the sidewalls of the insulating layers to form recesses; forming a plurality of discrete charge storage segments on the sidewalls of the sacrificial layers after the recessing; forming a tunneling layer on the discrete charge storage segments; forming a semiconductor layer on the tunneling layer; removing the sacrificial layers to form a plurality of void spaces each between adjacent ones of the insulating layers, the void spaces exposing the discrete charge storage segments; forming a blocking layer lining inner surfaces of the void spaces; and forming a plurality of conductive layers in the void spaces.

In some embodiments of the method, recessing the sidewalls of the sacrificial layers or the sidewalls of the insulating layers comprises etching the sidewalls of the sacrificial layers to form the recesses; wherein forming the discrete charge storage segments comprises selectively depositing the discrete charge storage segments on the recessed sidewalls of the sacrificial layers, and each of the discrete charge storage segments has an outer surface substantially even with the sidewalls of the insulating layers.

In some embodiments of the method, recessing the sidewalls of the sacrificial layers or the sidewalls of the insulating layers comprises etching the sidewalls of the sacrificial layers to form the recesses; wherein forming the discrete charge storage segments comprises selectively depositing the discrete charge storage segments on the recessed sidewalls of the sacrificial layers; wherein forming the tunneling layer comprises partially filling the recesses with the tunneling layer, thereby forming remaining spaces in the recesses; wherein forming the semiconductor layer comprises fully filling the remaining spaces with the semiconductor layer such that the semiconductor layer has corners in the remaining spaces.

In some embodiments of the method, recessing the sidewalls of the sacrificial layers or the sidewalls of the insulating layers comprises etching the sidewalls of the insulating layers to form the recesses, wherein each sacrificial layer has a protrusion protruding past the sidewalls of the insulating layers, and the protrusion has an exposed upper surface, an exposed lower surface and an exposed side surface; wherein forming the discrete charge storage segments comprises forming the discrete charge storage segments covering the exposed upper surfaces, the exposed lower surfaces and the exposed side surfaces.

It is to be understood that both the foregoing general description and the following detailed description are by examples, and are intended to provide further explanation of the present disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are cross-sectional views illustrating a method for manufacturing a memory device according to some embodiments of the present disclosure.

FIGS. 2A-2G are cross-sectional views illustrating a method for manufacturing a memory device according to yet some embodiments of the present disclosure.

FIGS. 3A-3E are cross-sectional views illustrating a method for manufacturing a memory device according to yet some embodiments of the present disclosure.

FIGS. 4A-4E are cross-sectional views illustrating a method for manufacturing a memory device according to yet some embodiments of the present disclosure.

FIGS. 5A-5G are cross-sectional views illustrating a method for manufacturing a memory device according to yet some embodiments of the present disclosure.

FIG. 6 is a cross-sectional view illustrating a memory device according to some embodiments of the present disclosure.

FIG. 7 is a cross-sectional view illustrating a memory device according to some embodiments of the present disclosure.

FIG. 8 is a cross-sectional view illustrating a memory device according to some embodiments of the present disclosure.

FIG. 9 is a cross-sectional view illustrating a memory device according to some embodiments of the present disclosure.

FIG. 10 is a cross-sectional view illustrating a memory device according to some embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or step in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−20% of the number described or other values as understood by person skilled in the art. For example, the term “about 5 nm” encompasses the dimension range from 4.0 nm to 6.0 nm.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

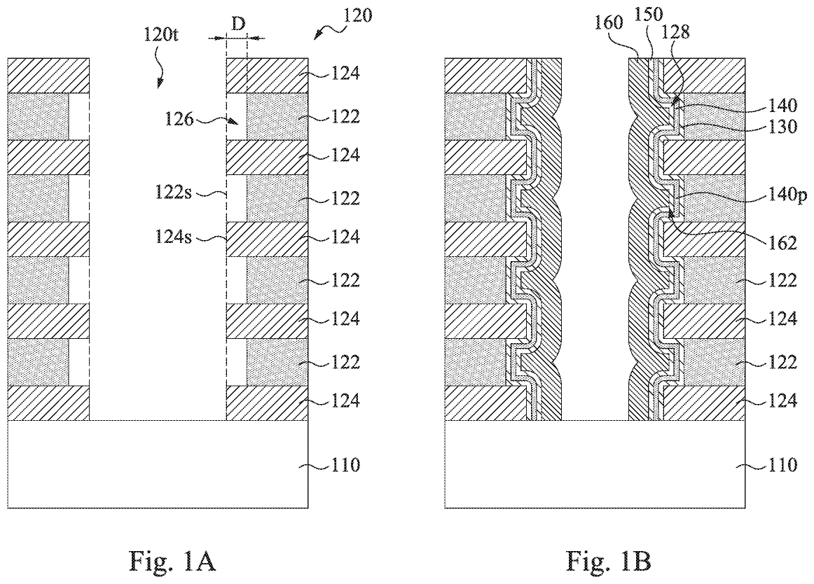

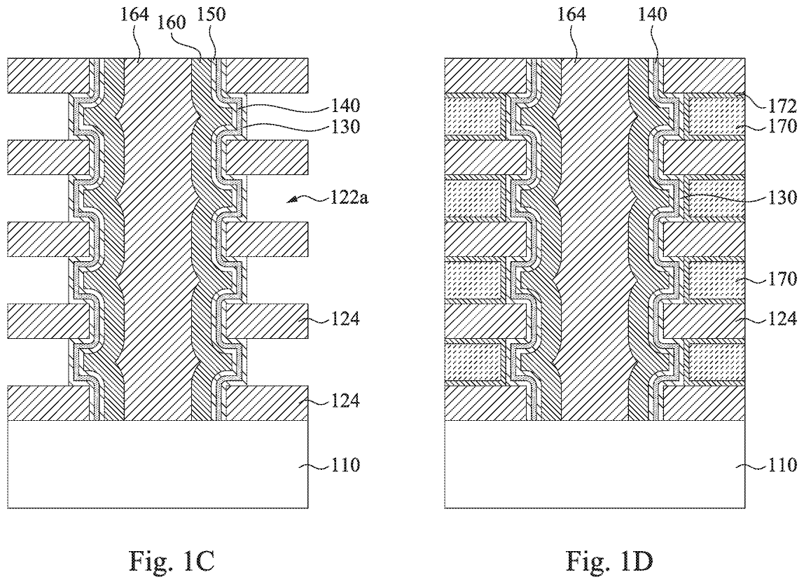

FIGS. 1A-1D are cross-sectional views illustrating a method for manufacturing a memory device according to some embodiments of the present disclosure. The illustrative method comprises a step of, as illustrated in FIG. 1A, forming at least a stack 120 (i.e., one or more stacks) comprising alternately arranged selective function layers 122 and insulating layers 124. The stack(s) 120 may be formed on a semiconductor substrate 110. While a plurality of stacks 120 are formed on the semiconductor substrate 110, spacing such as a trench 120t is present between adjacent stacks 120. In the stack 120, each of the selective function layers 122 and each of the insulating layers 124 has a sidewall such as sidewall 122s and sidewall 124s. In some examples, the selective function layers 122 may be sacrificial layers made of silicon nitride or the like, which will be replaced with metal gates in the subsequent processes. In yet some examples, however, the selective function layers 122 may be polysilicon layers that are not replaced and functions as gate electrodes in the final devices. In addition, the insulating layers 124 may be formed of any suitable insulating material different from the selective function layers 122, for example silicon oxide or the like. The thicknesses of the selective function layers 122 and insulating layers 124 may be ranged from several nanometers to several hundreds of nanometers according to some embodiments of the present disclosure.

After the stack 120 is formed, as illustrated in FIG. 1A, the sidewalls 122s of the selective function layers 122 are recessed to form the recesses 126 between adjacent insulating layers 124. The recessing process may be carried out by any suitable process, such as a reactive-ion etching (RIE) techniques or a wet etching process or other suitable etching processes. In some examples, the recesses 126 may have a depth D ranged from 80 angstroms (A) to 200 A, specifically 100-150 A.

As illustrated in FIG. 1B, a blocking layer 130 and a charge storage layer 140 are sequentially formed overlying the recessed sidewalls of the selective function layers 122 and the sidewalls of the insulating layers 124 after the sidewalls 122s of the selective function layers 122 is recessed. In some embodiments, the blocking layer 130 and the charge storage layer 140 are formed in a conformal manner so that the blocking layer 130 and the charge storage layer 140 partially fill the recesses 126. Therefore, there are remaining spaces 128 presented in the recesses 126. It is noted that the charge storage layer 140 is bent (or curved) due to the formed recesses 126. In some examples, the blocking layer 130 may comprise silicon oxide, aluminum doped silicon oxide or other metal doped silicon oxide. In some examples, the charge storage layer 140 may comprise silicon nitride, silicon oxynitride (SixOyNz), silicon-rich nitride, storage layers including embedded nano-particles or the like. The charge storage layer 140 with the bent structures provides certain technical effects, which will be described in detail hereinafter.

Thereafter, a tunneling layer 150 is formed on the charge storage layer 140, as shown in FIG. 1B. In some embodiments, the tunneling layer 150 is formed in a conformal manner, and the remaining spaces 128 are not fully filled with the tunneling layer 150. In examples, the tunneling layer 150 may comprise silicon dioxide or oxynitride or the concept of bandgap-engineering concept via double or triple-layers or the like.

A semiconductor layer 160 is formed on the tunneling layer 150. The semiconductor layer 160 fully fills the remaining spaces 128 such that the semiconductor layer 160 has corners 162 in the remaining spaces 128. In examples, the semiconductor layer 160 has an inner surface (e.g., the interface between the semiconductor layer 160 and the tunneling layer 150) that is substantially conformal with the tunneling layer 150 and the charge storage layer 140. The semiconductor layer 160, for example, may be made of polysilicon or other suitable semiconductor materials. In yet some examples, each corner 162 of the semiconductor layer 160 has an angle ranged from 80 degrees to 110 degrees, for example about 90 degrees.

It is noted that the semiconductor layer 160 with corners 162 can reduce the operating voltages of the memory devices. In specifics, the corners 162 provide relatively stronger electrical field to the charge storage layer 140. Therefore, the operating voltages of memory device may be reduced. In addition, the charge storage layer 140 with the bent structures significantly improves the reliability of the memory devices. In particular, because the bent structures of the charge storage layer 140 increases the difficulties of the charge migration, the charges trapped in the storage layer 140 are prone to be confined within the bent structures in the recesses 126 (shown in FIG. 1A), such as the portion 140p of the charge storage layer 140 adjacent to the selective function layer 122 depicted in FIG. 1B. Accordingly, the charges are confined in the desired cells of the storage layer 140 even though the operation voltage is decreased due to the contribution of the corners 162 of the semiconductor layer 160. Further, in some embodiments, the blocking layer 130, the charge storage layer 140, and the tunneling layer 150 may be conformally formed in sequence, and the manufacturing processes are simple, that implies the manufacturing processes being cost-effective.

As illustrated in FIG. 1C, an insulating structure 164 may optionally be formed covering the semiconductor layer 160. While a plurality of stacks 120 are formed, the insulating structure 164 may be formed filling the spacing between adjacent stacks 120 (e.g., trenches 120t indicated in FIG. 1A).

Thereafter, the selective function layers 124 may be replaced with metal layers 170 according to some embodiments, as illustrated in FIGS. 1C and 1D. As shown, the selective function layers 124 are removed to form void spaces 122a each between adjacent insulating layers 124, the void spaces 122a exposing the blocking layer 130. Thereafter, a metal layer 170 and a high K (i.e., high dielectric constant) layer 172 are formed in each of the void spaces 122a. It is noted that the high K layer(s) 172 is not necessary for the memory devices shown in FIG. 1D. In examples, the metal layers 170 may comprise titanium nitride, copper, tungsten, or platinum, or the like.

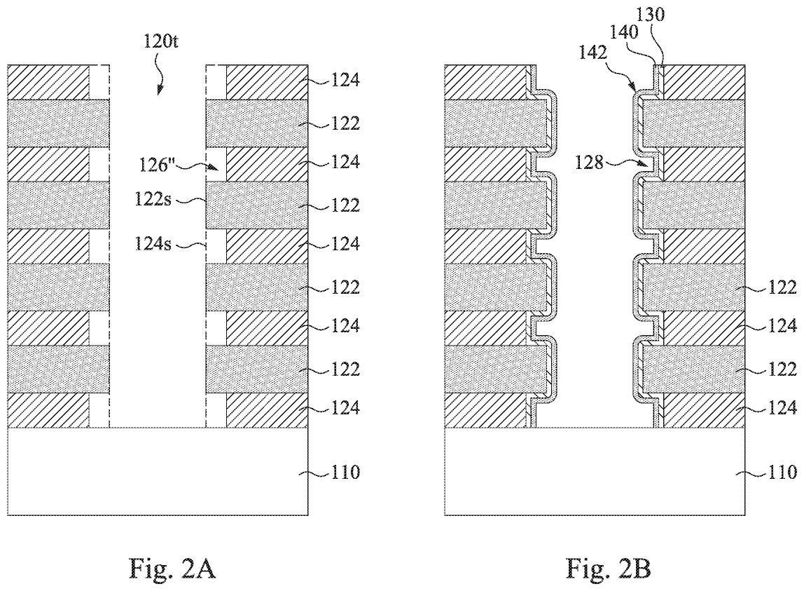

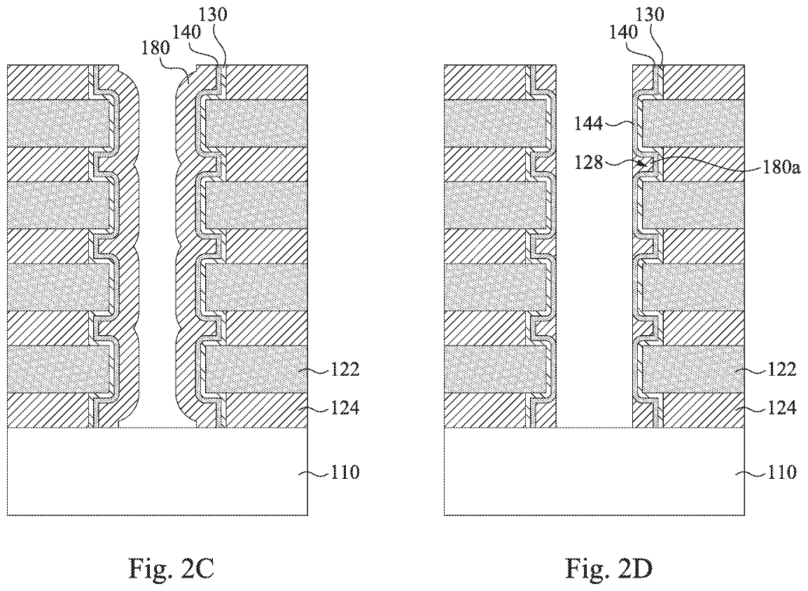

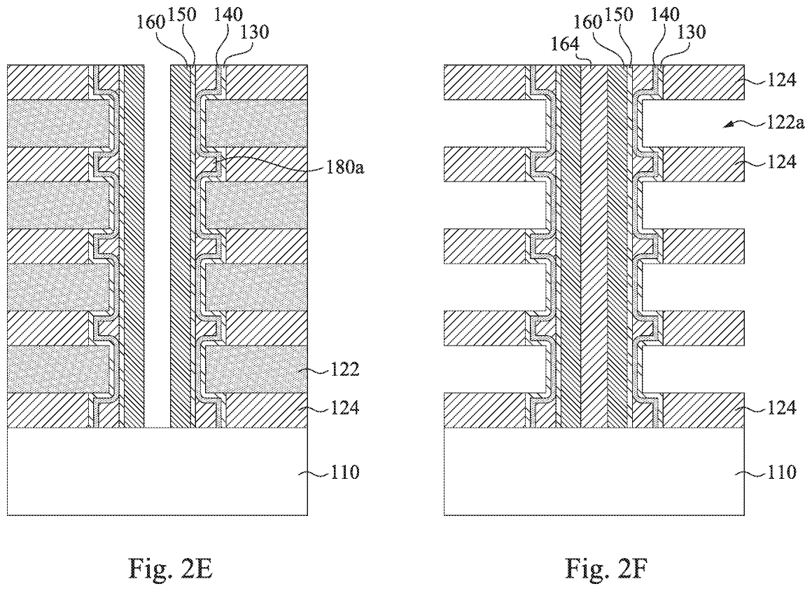

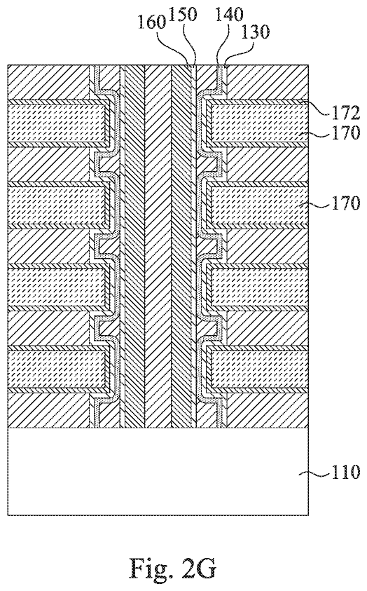

FIGS. 2A-2G are cross-sectional views illustrating a method for manufacturing a memory device according to yet some embodiments of the present disclosure. Reference numerals are repeated hereinafter to show the same or similar features and the description above applies equally to the embodiments described below. The illustrative method comprises a step of, as illustrated in FIG. 2A, forming at least a stack 120 (i.e., one or more stacks) comprising alternately arranged selective function layers 122 and insulating layers 124. The stack(s) 120 may be similar to or the same as these described hereinbefore in connection with FIG. 1A, and therefore the details are not repeated herein.

After the stack 120 is formed, as illustrated in FIG. 2A, the sidewalls 124s of the insulating layers 124 are recessed to form the recesses 126″ between adjacent the selective function layers 122. The recessing processes may be similar to or the same as these described hereinbefore in connection with FIGS. 1A-1D, and therefore the detailed description is not repeated herein.

As illustrated in FIG. 2B, a blocking layer 130 and a charge storage layer 140 are sequentially formed overlying the sidewalls of the selective function layers 122 and the recessed sidewalls of the insulating layers 124. The blocking layer 130 and the charge storage layer 140 partially fill the recesses 126″, thereby forming remaining spaces 128 in the recesses 126″.

It is noted that the charge storage layer 140 is bent (or curved) due to the formed recesses 126″. The charge storage layer 140 with the bent structures 142 provides certain technical effects. Specifically, as described hereinbefore in connection with FIGS. 1A-1D, the bent structures 142 significantly improve the reliability of the memory devices. In particular, the charges trapped in the charge storage layer 140 are prone to be confined within the bent structures because the bent structures 142 of the charge storage layer 140 increases the difficulties of the charge migration. Accordingly, the charges are confined in the desired cells of the storage layer 140.

As illustrated in FIG. 2C, a dielectric layer 180 is formed covering the charge storage layer 140 and fully filling the remaining spaces 128 according to some examples. Thereafter, as shown in FIG. 2D, extra portions of the dielectric layer 180 is removed to expose portions 144 of the charge storage layer 140, whereas the remained portions 180a of the dielectric layer 180 fills the remaining spaces 128. In some examples, the remained portions 180a and the exposed portions 144 of the charge storage layer 140 constitute a substantially flat vertical surface. As shown in FIG. 2E, a tunneling layer 150 is formed on the charge storage layer 140 and the remained portions 180a of the dielectric layer 180. Thereafter, a semiconductor layer 160 is formed on the tunneling layer 150.

As illustrated in FIG. 2F, an insulating structure 164 may be optionally formed covering the semiconductor layer 160. While a plurality of stacks 120 are formed, the insulating structure 164 may be formed filling the spacing between adjacent stacks 120 (e.g., trenches 120t indicated in FIG. 1A). Thereafter, the selective function layers 124 may be replaced with metal layers 170 according to some embodiments, as illustrated in FIGS. 2F and 2G. As shown, the selective function layers 124 are removed to form void spaces 122a each between adjacent insulating layers 124, the void spaces exposing the blocking layer 130. Thereafter, a metal layer 170 and a high K (i.e., high dielectric constant) layer 172 are formed in each of the void spaces 122a. It is noted that the high K layer(s) 172 is not necessary for the memory devices shown in FIG. 2G.

In view of various embodiments illustrated in FIGS. 1A-1D and FIGS. 2A-2G, the embodiments of the present disclosure provide a method for manufacturing a memory device. The method comprises the following steps: forming a stack (e.g., stack 120) comprising alternately arranged selective function layers and insulating layers; recessing the sidewalls of the selective function layers (e.g., selective function layers 122 in FIG. 1A) or the sidewalls of the insulating layers (e.g., insulating layers 124 in FIG. 2A) to form recesses (e.g., recesses 126 in n FIG. 1A or recesses 126″ in FIG. 2A); sequentially forming a blocking layer (e.g., blocking layer 130) and a charge storage layer (e.g., charge storage layer 140) overlying the sidewalls of the selective function layers and the sidewalls of the insulating layers, wherein the blocking layer and the charge storage layer partially fill the recesses, thereby forming remaining spaces in the recesses; forming a tunneling layer (e.g., tunneling layer 150) on the charge storage layer; and forming a semiconductor layer (e.g., semiconductor layer 160) on the tunneling layer.

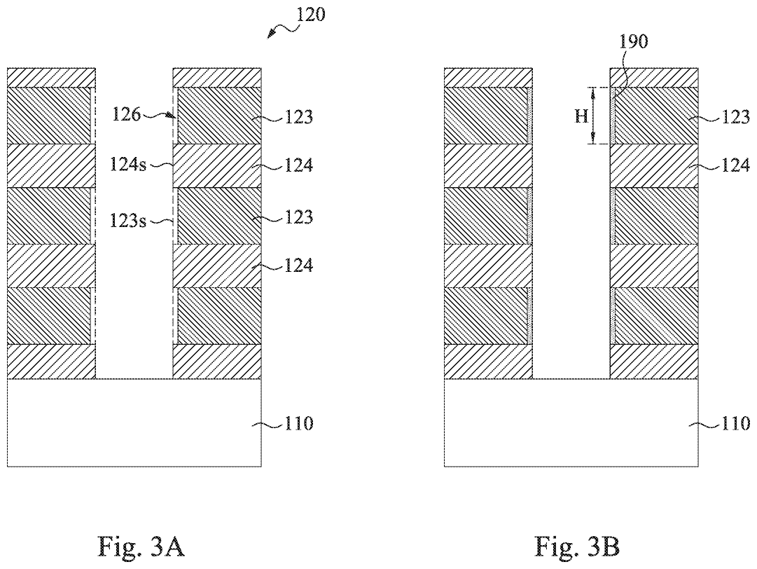

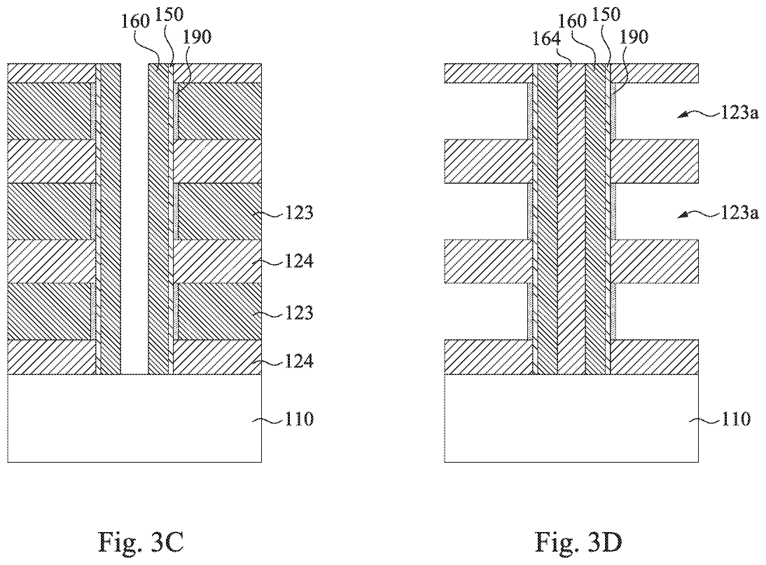

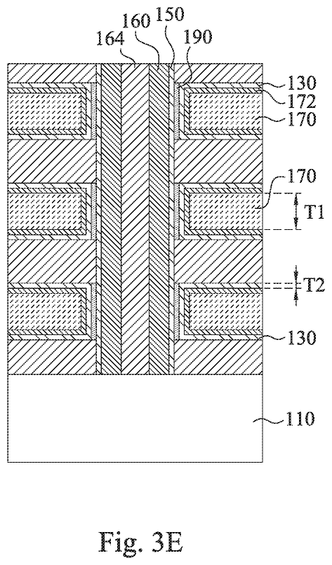

FIGS. 3A-3E are cross-sectional views illustrating a method for manufacturing a memory device according to yet some embodiments of the present disclosure. Reference numerals are repeated hereinafter to show the same or similar features and the description above applies equally to the embodiments described below. The illustrative method comprises a step of, as illustrated in FIG. 3A, forming at least a stack 120 (i.e., one or more stacks) comprising alternately arranged sacrificial layers 123 and insulating layers 124. In the stack 120, each of the sacrificial layers 123 and each of the insulating layers 124 has a sidewall such as sidewall 123s and sidewall 124s. In some examples, the sacrificial layers 123 may include or consist of polysilicon. In yet some examples, the insulating layers 124 may include or consist of silicon oxide or silicon oxynitride. After the stack 120 is formed, the sidewalls 123s of the sacrificial layers 123 is recessed to form recesses 126.

As illustrated in FIG. 3B, a plurality of discrete charge storage segments 190 is formed on the recessed sidewalls of the sacrificial layers 123. In some embodiments, the discrete charge storage segments 190 is formed by a selectively depositing process to form the discrete charge storage segments 190 on the recessed sidewalls of the sacrificial layers 123. In examples, the discrete charge storage segments 190 includes or consists of silicon nitride which may be selectively deposited merely on certain material such as polysilicon, in which the deposited material is not formed on the sidewall 124s of the insulating layers 124. That is, the selectively deposited material of the charge storage segments 190 is automatically or naturally aligned with the sacrificial layers 123. In addition, adjacent charge storage segments 190 are separated by a corresponding insulating layer 124 there between. In yet some examples, the discrete charge storage segments 190 fills the recesses 126, and each of the discrete charge storage segments 190 has an outer surface substantially even with the sidewalls 124s of the insulating layers 124. Please note that the height H of each discrete charge storage segments 190 is determined by the thickness of the sacrificial layers 123, and the discrete charge storage segments 190 may be precisely formed.

As illustrated in FIG. 3C, a tunneling layer 150 is formed on the discrete charge storage segments 190 and covers the sidewall of the insulating layers 124. Thereafter, a semiconductor layer 160 is formed on the tunneling layer 150.

As illustrated in FIG. 3D, an insulating structure 164 may be optionally formed covering the semiconductor layer 160. While a plurality of stacks 120 are formed, the insulating structure 164 may be formed filling the spacing between adjacent stacks 120. Thereafter, the sacrificial layers 123 are removed to form a plurality of void spaces 123a. Each of the void spaces 123a is between adjacent insulating layers 124. In some embodiments, the discrete charge storage segments 190 are exposed out through the void spaces 123a.

As illustrated in FIG. 3E, a blocking layer 130 is formed lining inner surfaces of the void spaces 123a. In some embodiments, the blocking layer 130 is in contact with the exposed discrete charge storage segments 190. Thereafter, a conductive layers 170 and a high K layer 172 are formed in each of the void spaces 123a. Because of the blocking layers 130 are formed prior to the formation of the conductive layers 170, the thickness of each conductive layer 170 is less than the height H (shown in FIG. 3B) of each discrete charge storage segment 190. In examples, the difference between the height H of each discrete charge storage segment 190 and the thickness T1 of each conductive layer 170 is substantially equal to or greater than 2 folds of the thickness T2 of the blocking layer 130.

It is further noted that the discrete charge storage segments 190 provides certain technical effects. Particular, the charges trapped in each of the discrete charge storage segments 190 is confined therein and the possibility of charge migration to neighboring memory cells is minimized because each discrete charge storage segment 190 is independent and separated from one another. Therefore, the reliability of the memory device is significantly improved.

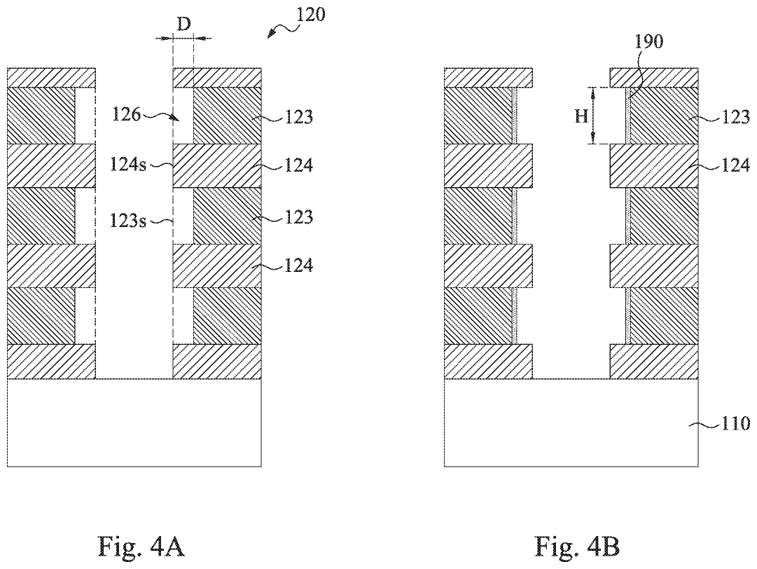

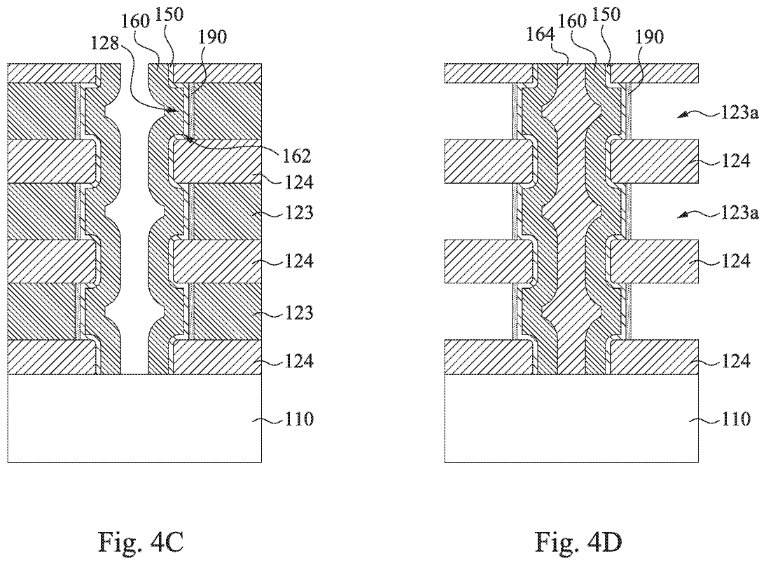

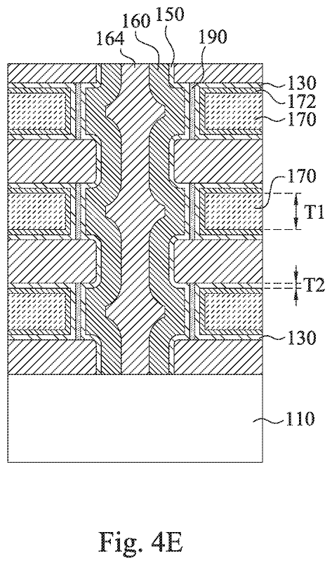

FIGS. 4A-4E are cross-sectional views illustrating a method for manufacturing a memory device according to yet some embodiments of the present disclosure. Reference numerals are repeated hereinafter to show the same or similar features and the description above applies equally to the embodiments described below. The illustrative method comprises a step of, as illustrated in FIG. 4A, forming at least a stack 120 comprising alternately arranged sacrificial layers 123 and insulating layers 124. The stack 120 may be similar to or the same as these described hereinbefore in connection with FIG. 3A, and therefore the details are not repeated herein. After the stack 120 is formed, the sidewalls 123s of the sacrificial layers 123 is recessed to form recesses 126.

As illustrated in FIG. 4B, a plurality of discrete charge storage segments 190 is formed on the recessed sidewalls of the sacrificial layers 123. The discrete charge storage segments 190 in FIG. 4B may be formed by the approaches described above in connection with FIG. 3B. The height H of each discrete charge storage segments 190 is determined by the thickness of the sacrificial layers 123. It is noted that the discrete charge storage segments 190 in FIG. 4B are not formed to fully fill the recesses 126. For example, the recesses 126 shown in FIG. 4A may be formed to have a depth D greater than that of the recesses 126 shown in FIG. 3A. Therefore, the discrete charge storage segments 190 in FIG. 4B may be formed with a desired thickness, and the recesses 126 are not fully filled.

As illustrated in FIG. 4C, a tunneling layer 150 is formed on the discrete charge storage segments 190 and covers the sidewall of the insulating layers 124. The tunneling layer 150 partially fills the recesses 126, and therefore remaining spaces 128 are present in the recesses 126. Thereafter, a semiconductor layer 160 is formed on the tunneling layer 150. The semiconductor layer 160 fully fills remaining spaces 128 (or the recesses 126) such that the semiconductor layer 160 has corners 162 in the remaining spaces 128. The corners 162 of the semiconductor layer 160 provide the technical effect that reduces the operation voltage of the memory device due to the generation of relatively stronger electrical field, as described hereinbefore in connection with FIGS. 1A-1D.

As illustrated in FIG. 4D, an insulating structure 164 may be optionally formed covering the semiconductor layer 160. Thereafter, the sacrificial layers 123 are removed to form a plurality of void spaces 123a. Each of the void spaces 123a is between adjacent insulating layers 124, and the discrete charge storage segments 190 are exposed out through the void spaces 123a.

As illustrated in FIG. 4E, a blocking layer 130 is formed lining inner surfaces of the void spaces 123a. In some embodiments, the blocking layer 130 is in contact with the exposed discrete charge storage segments 190. Thereafter, a conductive layers 170 and a high K layer 172 are formed in each of the void spaces 123a. Because of the blocking layers 130 are formed prior to the formation of the conductive layers 170, the thickness T1 of each conductive layer 170 is less than the height H (shown in FIG. 4B) of each discrete charge storage segment 190. In examples, the difference between the height H of each discrete charge storage segment 190 and the thickness T1 of each conductive layer 170 is substantially equal to or greater than 2 folds of the thickness T2 of the blocking layer 130.

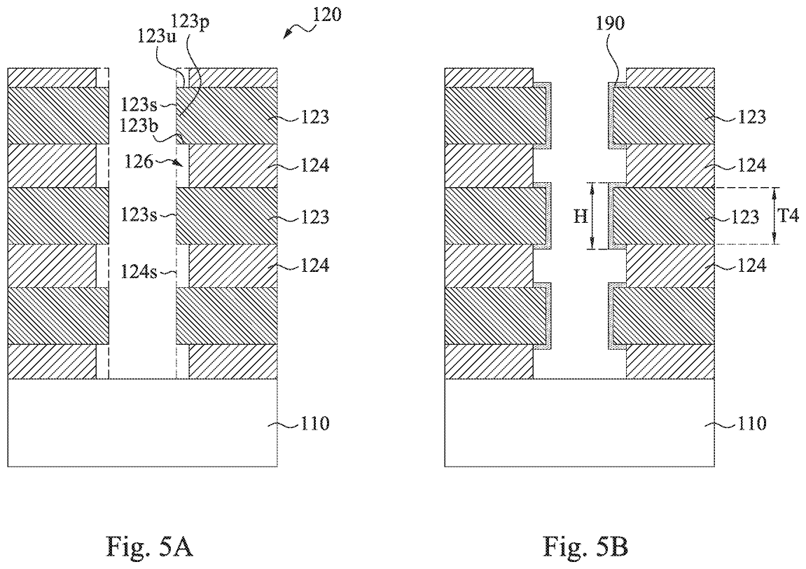

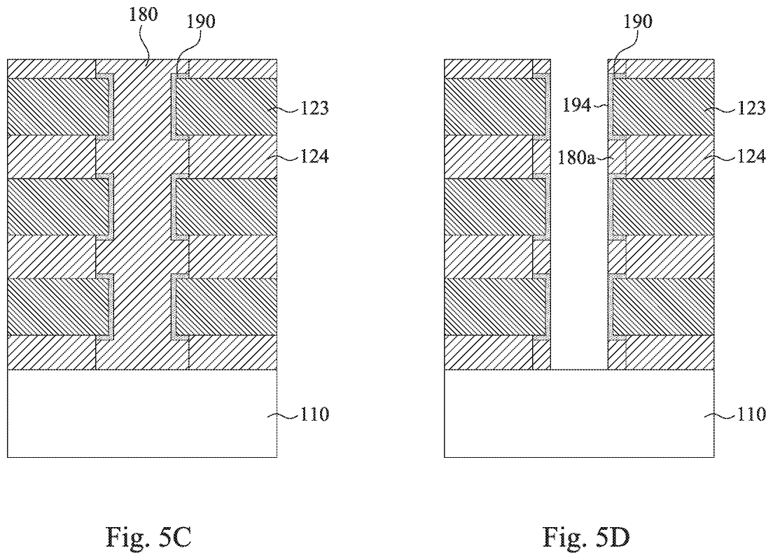

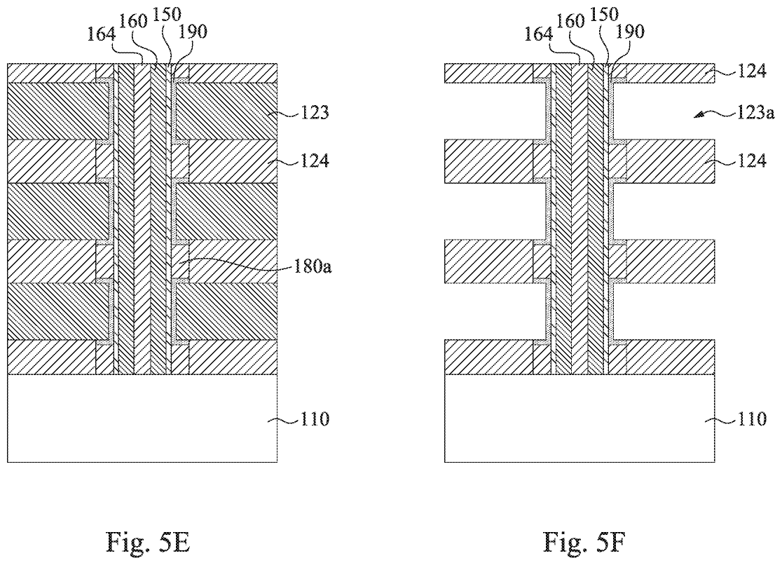

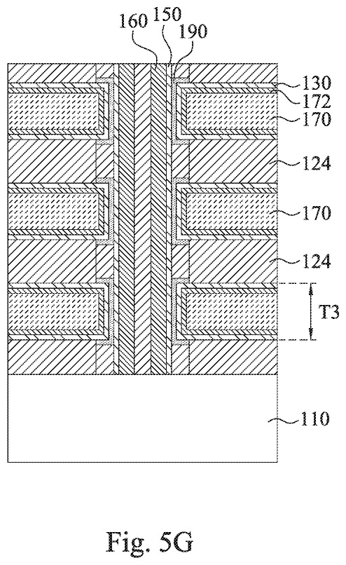

FIGS. 5A-5G are cross-sectional views illustrating a method for manufacturing a memory device according to yet some embodiments of the present disclosure. Reference numerals are repeated hereinafter to show the same or similar features and the description above applies equally to the embodiments described below. The illustrative method comprises a step of forming at least a stack 120, as illustrated in FIG. 5A. The stack 120 comprises alternately arranged sacrificial layers 123 and insulating layers 124. The stack 120 may be similar to or the same as these described hereinbefore in connection with FIG. 3A, and therefore the details are not repeated herein. After the stack 120 is formed, the sidewalls 124s of the insulating layers 124 is recessed to form recesses 126. After the recesses 126 are formed, each sacrificial layer 123 has a protrusion 123p protruding past the recessed sidewalls of the insulating layers 124. Each of the protrusions 123p of the sacrificial layers 123 has an exposed upper surface 123u, an exposed lower surface 123b and an exposed side surface 123s.

As illustrates in FIG. 5B, a plurality of discrete charge storage segments 190 is formed covering the exposed upper surface 123u, the exposed lower surface 123b and the exposed side surface 123s. In some embodiments, the discrete charge storage segments 190 is formed by a selectively depositing process to form the discrete charge storage segments 190 on the exposed surfaces of the sacrificial layers 123. In examples, the discrete charge storage segments 190 includes or consists of silicon nitride, which may be selectively deposited merely on certain material such as polysilicon, in which the deposited material is not formed on the insulating layers 124. That is, discrete charge storage segments 190 is deposited covering the protrusions 123p of the sacrificial layers 123. It is noted that each discrete charge storage segment 190 has a height H greater than the thickness T4 of each sacrificial layers 123.

As illustrates in FIG. 5C, a dielectric layer 180 is formed covering the discrete charge storage segments 190 and fully filling the recesses 126 (shown in FIG. 5A).

As illustrates in FIG. 5D, an extra portion of the dielectric layer 180 is removed to expose portions 194 of the discrete charge storage segments 190. The remained portions 180a of the dielectric layer 180 still fill the recesses 126.

As illustrates in FIG. 5E, a tunneling layer 150 is forming on the discrete charge storage segments 190 and covers the remained portions 180a of the dielectric layer 180. Thereafter, a semiconductor layer 160 is formed on the tunneling layer 150, and an insulating structure 164 may optionally formed on the semiconductor layer 160.

As illustrates in FIG. 5F, the sacrificial layers 123 is removed to form a plurality of void spaces 123a. Each void space 123a is between adjacent insulating layers 124. The discrete charge storage segments 190 are exposed through the void spaces 123a.

As illustrates in FIG. 5G, a blocking layer 130 is formed lining inner surfaces of the void spaces 123a. In some embodiments, the blocking layer 130 is in contact with the exposed discrete charge storage segments 190. Thereafter, a conductive layers 170 and a high K layer 172 are formed in each of the void spaces 123a. It is noted that the height H (shown in FIG. 5B) of each discrete charge storage segment 190 is greater than the total thickness T3 of the corresponding blocking layer 130, conductive layer 170 and high K layer 172.

In view of various embodiments illustrated in FIGS. 3A-3E, 4A-4E, and FIGS. 5A-5G, the embodiments of the present disclosure provide a method for manufacturing a memory device. The method comprises the following steps: forming a stack (e.g., stack 120) comprising alternately arranged sacrificial layers (e.g., sacrificial layers 123) and insulating layers (e.g., insulating layers 124); recessing the sidewalls of the sacrificial layers (e.g., sidewalls 123s of the sacrificial layers 123 in FIG. 3A and FIG. 4A) or the sidewalls of the insulating layers (e.g., sidewalls 124s of the insulating layers 124 in FIG. 5A) to form recesses (e.g., recesses 126); forming a plurality of discrete charge storage segments (e.g., discrete charge storage segments 190) on the sidewalls of the sacrificial layers after the recessing; forming a tunneling layer (e.g., tunneling layer 150) on the discrete charge storage segments; forming a semiconductor layer (e.g., semiconductor layer 160) on the tunneling layer; removing the sacrificial layers (e.g., sacrificial layers 123) to form a plurality of void spaces (void spaces 123a) each between adjacent ones of the insulating layers, the void spaces exposing the discrete charge storage segments; forming a blocking layer (e.g., blocking layer 130) lining inner surfaces of the void spaces; and forming a plurality of conductive layers (e.g., conductive layers 170) in the void spaces.

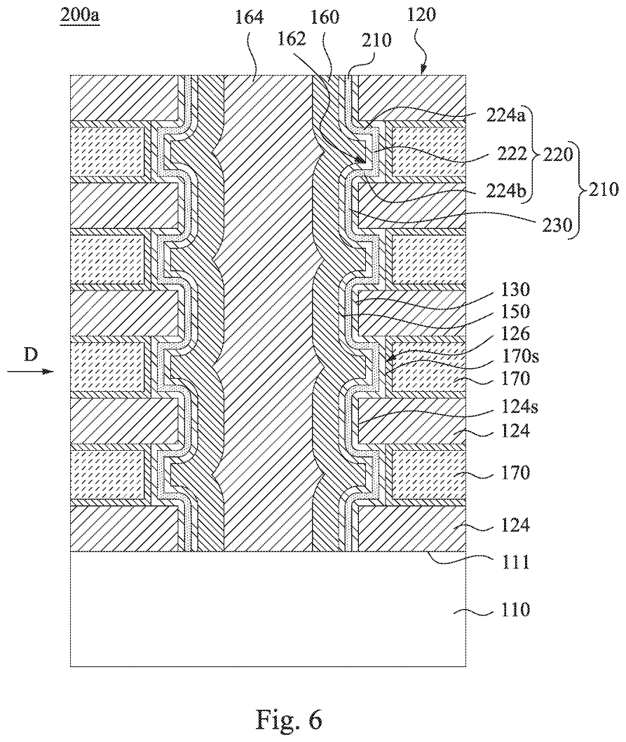

Another aspect of the present disclosure is to provide a memory device. FIG. 6 is a cross-sectional view illustrating a memory device 200a according to some embodiments of the present disclosure. The memory device 200a, for example, may be a 3D NAND FLASH memory device. The memory device 200a comprises a semiconductor substrate 110, at least a stack 120, a charge storage structure 210, a blocking layer 130, a tunneling layer 150, and a semiconductor layer 160.

The semiconductor substrate 110 has a principle surface 111 on which memory cells are fabricated. The semiconductor substrate 110, for example, may include silicon. In some embodiments, the semiconductor substrate 110 may include other elementary semiconductor such as for example germanium. In yet some embodiments, the semiconductor substrate 110 may include an alloy semiconductor such as for example silicon germanium, silicon germanium carbide, and the like. In yet some embodiments, the semiconductor substrate 110 may include a semiconductor-on-insulator (SOI) structure. In yet some embodiments, the semiconductor substrate 110 may include an epitaxial layer overlying a bulk semiconductor material.

The stack 120 is disposed on the principle surface 111 of the semiconductor substrate 110. The stack 120 comprises alternately arranged conductive layers 170 and insulating layers 124. The sidewalls 170s of the conductive layers 170 are recessed relative to the sidewalls 124s of the insulating layers 124 to define a plurality of recesses 126. In some examples, the conductive layers 170 may be made of doped or undoped polysilicon polysilicon or metallic materials such as titanium nitride, copper, tungsten and platinum. The present disclosure is not limited to the material described above, and one skilled in the art may select suitable material for the conductive layers 132 according to actual need. In some examples, the insulating layers 124 may be made of any suitable material such as silicon oxide or the like.

The charge storage structure 210 comprises a plurality of bent storage structures 220 and optionally a plurality of connecting portions 230. While the charge storage structure 210 include connecting portions 230, each connecting portion 230 interconnects adjacent bent storage structures 220. The bent storage structures 220 are arranged opposite to (or facing) the sidewalls 170s of the conductive layers 170. In particular, each bent storage structure 220 is substantially aligned with a corresponding one of the conductive layers 170 in a direction D parallel to the principle surface 111. Each bent storage structures 220 is at least partially accommodated in a corresponding recess 126. In some examples, each bent storage structure 220 comprises a vertical portion 222 and two horizontal portions 224a, 224b. Horizontal portions 224a, 224b extend from opposite sides of the vertical portion 222 away the neighboring conductive layer 170. Each vertical portion 222 is substantially aligned with the neighboring (or corresponding) conductive layer 170 in the direction D. In addition, while including the connecting portions 230, the connecting portions 230 are substantially aligned with the neighboring insulating layers 124 in the direction D.

The blocking layer 130 is at least partially interposed between the conductive layers 170 and the bent storage structures 220. In some examples, the blocking layer 130 covers the sidewalls 124 of the insulating layers 124 and extends into the recesses 126. The portions of the blocking layer 130 in the recesses 126 are located between the conductive layers 170 and the vertical portion 222 of the bent storage structures 220. In some examples, the blocking layer 130 is conformal with the charge storage structure 210.

The tunneling layer 150 is disposed on the charge storage structure 210. In some examples, the tunneling layer 150 covers the bent storage structures 220 and the connecting portions 230. In yet some examples, the tunneling layer 150 are conformal with the charge storage structure 210.

The semiconductor layer 160 is disposed on the tunneling layer 150. The semiconductor layer 160 has corners 162 Each of the corners 162 are located in the spaces defined by the vertical portion 222 and horizontal portions 224a, 224b of the bent storage structures 220. In yet some examples, each corner 162 of the semiconductor layer 160 has an angle ranged from 80 degrees to 110 degrees, for example about 90 degrees. Other features of the memory device 200a may refer to the embodiments described above in connection with FIGS. 1A-1D.

As mentioned above, the semiconductor layer 160 with corners 162 can reduce the operating voltages of the memory device 200a. In specifics, the corners 162 provide relatively stronger electrical field to the bent storage structures 220. Therefore, the operating voltages of memory device 200a may be reduced. In addition, the bent storage structures 220 significantly improves the reliability of the memory device 200a. In particular, the charges tend to be confined within the vertical portion 222 because the turning angle(s) of the bent storage structures 220 increases the difficulties of the charge migration. Accordingly, the charges are confined in the desired cells.

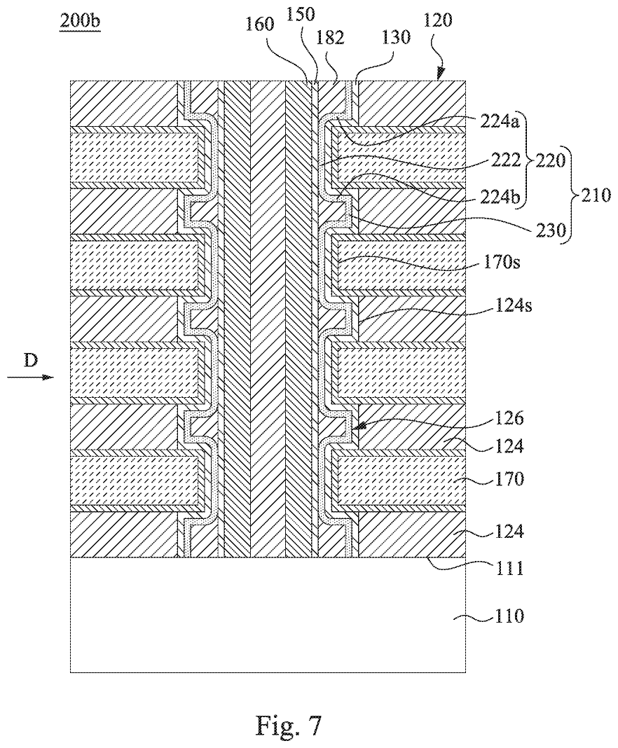

FIG. 7 is a cross-sectional view illustrating a memory device 200b according to some embodiments of the present disclosure. The memory device 200b comprises a semiconductor substrate 110, at least a stack 120, a charge storage structure 210, a blocking layer 130, a tunneling layer 150, and a semiconductor layer 160.

The stack 120 is disposed on the principle surface 111 of the semiconductor substrate 110. The stack 120 comprises alternately arranged conductive layers 170 and insulating layers 124. The stack 120 shown in FIG. 7 differs from the stack 120 shown in FIG. 6 in that sidewalls 124s of the insulating layers 124 are recessed relative to the sidewalls 170s of the conductive layer 170 to define a plurality of recesses 126.

The charge storage structure 210 comprises a plurality of bent storage structures 220 and optionally a plurality of connecting portions 230. While the charge storage structure 210 include connecting portions 230, each connecting portion 230 interconnects adjacent bent storage structures 220 and is accommodated in one of the recesses 126. Each bent storage structure 220 is substantially aligned with a corresponding one of the conductive layers 170 in a direction D parallel to the principle surface 111. Each bent storage structure 220 comprises a vertical portion 212 and two horizontal portions 214a, 214b. The two horizontal portions 214a, 214b extend from opposite sides of the vertical portion 212 towards the corresponding conductive layer 170. The two horizontal portions 214a, 214b are located at opposite sides of the corresponding conductive layer 170.

The blocking layer 130 is at least partially interposed between the conductive layers 170 and the bent storage structures 220. In some examples, the blocking layer 130 covers the sidewalls 124 of the insulating layers 124. The portions of the blocking layer 130 are located between the conductive layers 170 and the vertical portion 222 of the bent storage structures 220. In some examples, the blocking layer 130 is conformal with the charge storage structure 210.

In some embodiments, the memory device 200b further comprises dielectric structures 182 on the charge storage structure 210 and filling the recesses 126. Each of the dielectric structures 182 has a surface substantially flush with or even with the surface of the vertical portion 222 of the bent storage structures 220 according to some examples.

The tunneling layer 150 is disposed on the bent storage structures 220. In some embodiments, the tunneling layer 150 is in contact with the vertical portion 222 of the bent storage structures 220, and further covers the dielectric structures 182.

The semiconductor layer 160 is disposed on the tunneling layer 150. Other features of the memory device 200b may refer to the embodiments described above in connection with FIGS. 2A-2G.

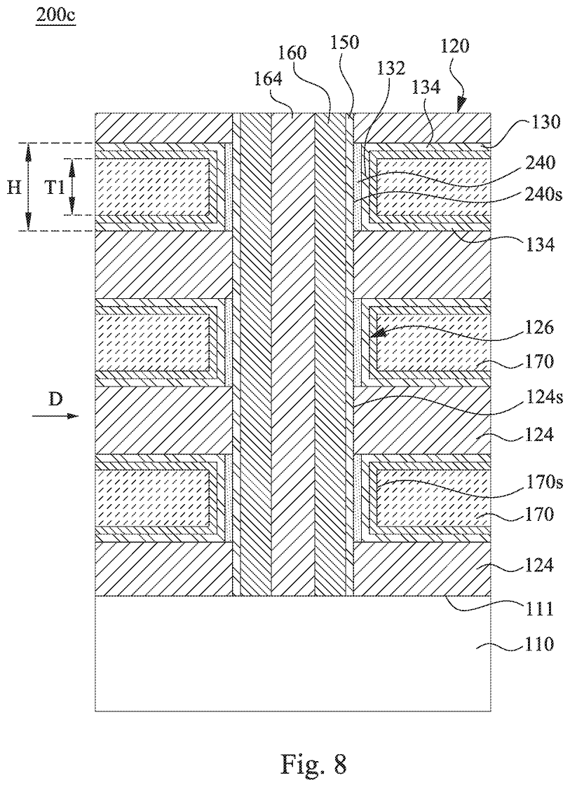

FIG. 8 is a cross-sectional view illustrating a memory device 200c according to some embodiments of the present disclosure. The memory device 200c comprises a semiconductor substrate 110, at least a stack 120, a plurality of discrete storage segments 240, a blocking layer 130, a tunneling layer 150, and a semiconductor layer 160.

The stack 120 is disposed on the principle surface 111 of the semiconductor substrate 110. Furthermore, the stack 120 comprises alternately arranged conductive layers 170 and insulating layers 124. The sidewalls 170s of the conductive layer 170 are recessed relative to the sidewalls 124s of the insulating layers 124 to define a plurality of recesses 126.

The discrete storage segments 240 are opposite to the sidewalls 170s of the conductive layers 170. Stated differently, each discrete storage segment 240 is substantially aligned with a corresponding one of the conductive layers 170, in a direction D parallel to the principle surface 111. The discrete storage segments 240 are accommodated in the recesses 126. In some examples, each of the discrete storage segments 240 has a sidewall 240s substantially flush with or even with the sidewalls 124s of the insulating layers 124. In yet some examples, each discrete storage segment 240 has a height H that is greater than the thickness T1 of each conductive layer 170.

The blocking layer 130 is at least partially interposed between the conductive layers 170 and the discrete storage segments 240. In some embodiments, the blocking layer 130 includes a plurality of vertical portions 132 and a plurality of horizontal portions 134 connected to the vertical portions 132. According to some examples, each vertical portion 132 faces the sidewall 170s of the corresponding conductive layer 170, and each horizontal portion 134 is positioned between adjacent conductive layer 170 and insulating layer 124.

The tunneling layer 150 is disposed on the discrete storage segments 240. In some embodiments, the tunneling layer 150 covers the sidewall 240s of the discrete storage segments 240 and the sidewalls 124s of the insulating layers 124.

The semiconductor layer 160 is disposed on the tunneling layer 150. Other features of the memory device 200c may refer to the embodiments described above in connection with FIGS. 3A-3E.

As discussed hereinbefore, the charges trapped in each of the discrete storage segments 240 is confined therein and the possibility of charge migration to neighboring memory cells is minimized because each discrete storage segment 240 is independent and separated from one another. Therefore, the reliability of the memory device is significantly improved.

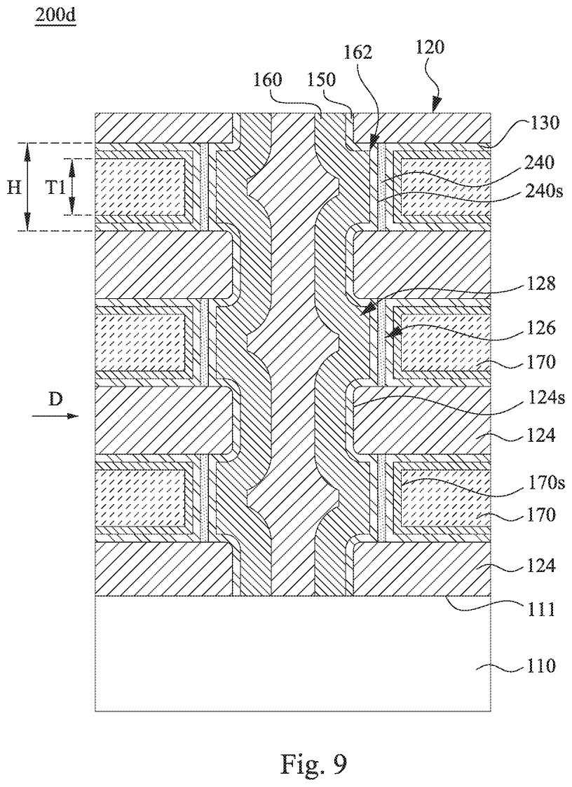

FIG. 9 is a cross-sectional view illustrating a memory device 200d according to some embodiments of the present disclosure. The memory device 200d comprises a semiconductor substrate 110, at least a stack 120, a plurality of discrete storage segments 240, a blocking layer 130, a tunneling layer 150, and a semiconductor layer 160.

The stack 120 is disposed on the principle surface 111 of the semiconductor substrate 110. Furthermore, the stack 120 comprises alternately arranged conductive layers 170 and insulating layers 124. The sidewalls 170s of the conductive layer 170 are recessed relative to the sidewalls 124s of the insulating layers 124 to define a plurality of recesses 126.

The discrete storage segments 240 are opposite to the sidewalls 170s of the conductive layers 170. Stated differently, each discrete storage segment 240 is substantially aligned with a corresponding one of the conductive layers 170, in a direction D parallel to the principle surface 111. The discrete storage segments 240 are accommodated in the recesses 126. In the embodiment shown in FIG. 9, the sidewall 240s of each discrete storage segment 240 is recessed relative to the sidewalls 124s of the insulating layers 124. In some examples, each discrete storage segment 240 has a height H greater than the thickness T1 of each conductive layer 170.

The blocking layer 130 is at least partially interposed between the conductive layers 170 and the discrete storage segments 240. The detailed embodiments of the blocking layer 130 in FIG. 9 may be the same as or similar to the blocking layer 130 in connection with FIG. 8, and the description thereof is omitted to avoid repetition.

The tunneling layer 150 is disposed on the discrete storage segments 240. In some embodiments, the tunneling layer 150 covers the sidewalls 124s of the insulating layers 124, and further extends into the recesses 126 to cover the sidewalls 240s of the discrete storage segment 240. The tunneling layer 150 does not fully fill the recesses 126, and therefore a remaining space 128 is present in each recess 126.

The semiconductor layer 160 is disposed on the tunneling layer 150. In some embodiments, the semiconductor layer 160 fully fills the remaining spaces 128 such that the semiconductor layer 160 has corners 162 in the remaining spaces 128. Other features of the memory device 200d may refer to the embodiments described above in connection with FIGS. 4A-4E.

As discussed hereinbefore, the semiconductor layer 160 with corners 162 can reduce the operating voltages of the memory device 200d. In specifics, the corners 162 provide relatively stronger electrical field to the discrete storage segments 240. Therefore, the operating voltages of memory device 200d may be reduced. In addition, the charges trapped in each of the discrete storage segments 240 is confined therein and the possibility of charge migration to neighboring memory cells is minimized because each discrete charge storage segment 240 is independent and separated from one another. Therefore, the reliability of the memory device 200d is significantly improved.

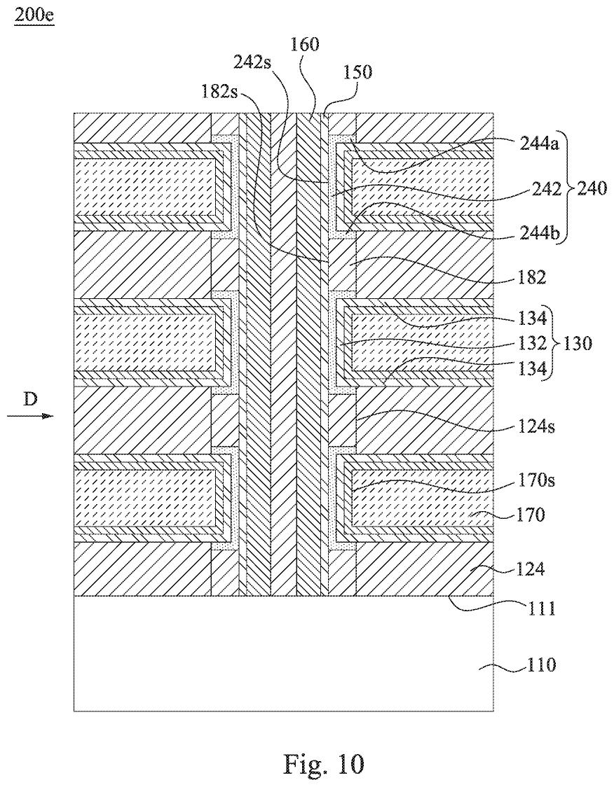

FIG. 10 is a cross-sectional view illustrating a memory device 200e according to some embodiments of the present disclosure. The memory device 200e comprises a semiconductor substrate 110, at least a stack 120, a plurality of discrete storage segments 240, a blocking layer 130, a tunneling layer 150, and a semiconductor layer 160.

The stack 120 is disposed on the principle surface 111 of the semiconductor substrate 110. Furthermore, the stack 120 comprises alternately arranged conductive layers 170 and insulating layers 124.

The discrete storage segments 240 are arranged opposite to sidewalls 170s of the conductive layers 170. In some embodiments, each discrete storage segment 240 is substantially aligned with a corresponding one of the conductive layers 170 in a direction D parallel to the principle surface 111. According to some examples, each of the discrete storage segments 240 comprises a vertical portion 242 and two flanges 244a, 244b extending from opposite edges of the vertical portion 242. The vertical portion 242 faces the sidewall 170s of the corresponding conductive layers 170. The two flanges 244a, 244b extends from the vertical portion 242 towards the corresponding conductive layer 170.

The blocking layer 130 at least partially interposed between the conductive layers 170 and the discrete storage segments 240. In some embodiments, the blocking layer 130 includes a plurality of vertical portions 132 and a plurality of horizontal portions 134 connected to the vertical portions 132. According to some examples, each vertical portion 132 faces the sidewall 170s of the corresponding conductive layer 170, and extends vertically between the corresponding conductive layer 170 and the vertical portion 242 of the discrete storage segment 240. On the other hand, each horizontal portion 134 is positioned between adjacent conductive layer 170 and insulating layer 124. Furthermore, the horizontal portions 134 extend laterally past the sidewalls 124s of the insulating layers 124.

The memory device 200e may optionally further comprise a plurality of dielectric structures 182 interposed between adjacent ones of the discrete storage segments 240. According to some examples, each dielectric structure 182 has a surface 182s that is substantially flush with or even with the outer surfaces 242s of the vertical portions 242 of the discrete storage segments 240.

The tunneling layer 150 is disposed on the discrete storage segments 240. In some embodiments, the tunneling layer 150 is in contact with the vertical portions 242 of the discrete storage segments 240, and further covers the dielectric structures 182.

The semiconductor layer 160 is disposed on the tunneling layer 150. Other features of the memory device 200e may refer to the embodiments described above in connection with FIGS. 5A-5G.

As discussed hereinbefore, the charges trapped in each of the discrete storage segments 240 is confined therein and the possibility of charge migration to neighboring memory cells is minimized because each discrete storage segment 240 is independent and separated from one another. Therefore, the reliability of the memory device 200e is significantly improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A memory device, comprising:
a semiconductor substrate having a principle surface;
a stack disposed on the principle surface of the semiconductor substrate and comprising alternately arranged conductive layers and insulating layers;
a charge storage structure comprising a plurality of bent storage structures or discrete storage segments, the bent storage structures or the discrete storage segments being opposite to sidewalls of the conductive layers, wherein each bent storage structure or each discrete storage segment is substantially aligned with a corresponding one of the conductive layers in a direction parallel to the principle surface;
a blocking layer at least partially interposed between the conductive layers and the bent storage structures or between the conductive layers and the discrete storage segments;
a tunneling layer on the bent storage structures or the discrete storage segments; and
a channel layer on the tunneling layer.

2. The memory device according to claim 1, wherein the charge storage structure comprises the bent storage structures, and the sidewalls of the conductive layers are recessed relative to sidewalls of the insulating layers to define a plurality of recesses, in which the bent storage structures are accommodated therein.

3. The memory device according to claim 2, wherein the charge storage structure further comprises a plurality of connecting portions each interconnected between adjacent ones of the bent storage structures.

4. The memory device according to claim 3, wherein the blocking layer and the tunneling layer are conformal with the charge storage structure.

5. The memory device according to claim 1, wherein the charge storage structure comprises the bent storage structures, and sidewalls of the insulating layers are recessed relative to the sidewalls of the conductive layers to define a plurality of recesses;
wherein the charge storage structure further comprises a plurality of connecting portions each interconnected between adjacent ones of the bent storage structures, and the connecting portions are accommodated in the recesses.

6. The memory device according to claim 5, wherein the blocking layer is conformal with the charge storage structure, whereas the tunneling layer is not conformal with the charge storage structure.

7. The memory device according to claim 6, wherein each bent storage structure comprises a vertical portion and two horizontal portions extending from opposite sides of the vertical portion towards the corresponding one of the conductive layers.

8. The memory device according to claim 1, wherein the charge storage structure comprises the discrete storage segments, and the sidewalls of the conductive layers are recessed relative to sidewalls of the insulating layers to define a plurality of recesses, in which the discrete storage segments are accommodated.

9. The memory device according to claim 8, wherein the discrete storage segments have sidewalls substantially flush with the sidewalls of the insulating layers, and each of the discrete storage segments has a height greater than a thickness of each of the conductive layers.

10. The memory device according to claim 1, wherein the charge storage structure comprises the discrete storage segments, and the sidewalls of the conductive layers are recessed relative to sidewalls of the insulating layers to define a plurality of recesses accommodating the discrete storage segments, wherein portions of the tunneling layer and the channel layer are located in the recesses.

11. The memory device according to claim 1, wherein the charge storage structure comprises the discrete storage segments, and each of the discrete storage segments comprises a vertical portion facing the sidewall of the corresponding one of the conductive layers and two flanges extending from the vertical portion towards the corresponding one of the conductive layers.

12. A method for manufacturing a memory device, the method comprising:
forming a stack comprising alternately arranged selective function layers and insulating layers, the selective function layers and insulating layers having respective sidewalls;
recessing the sidewalls of the selective function layers or the sidewalls of the insulating layers to form recesses;
sequentially forming a blocking layer and a charge storage layer overlying the sidewalls of the selective function layers and the sidewalls of the insulating layers, wherein the blocking layer and the charge storage layer partially fill each of the recesses, thereby forming a remaining space in each of the recesses;
forming a tunneling layer on the charge storage layer; and
forming a semiconductor layer on the tunneling layer.

13. The method according to claim 12, wherein recessing the sidewalls of the selective function layers or the sidewalls of the insulating layers comprises etching the sidewalls of the selective function layers to form the recesses,
wherein forming the semiconductor layer comprises fully filling the remaining spaces with the semiconductor layer such that the semiconductor layer has corners in the remaining spaces.

14. The method according to claim 13, further comprising replacing the selective function layers with conductive layers.

15. The method according to claim 12, wherein recessing the sidewalls of the selective function layers or the sidewalls of the insulating layers comprises etching the sidewalls of the insulating layers to form the recesses.

16. The method according to claim 15, prior to forming the tunneling layer, further comprising:
forming a dielectric layer covering the charge storage layer and fully filling the remaining spaces; and
removing an extra portion of the dielectric layer to expose portions of the charge storage layer.

17. A method for manufacturing a memory device, the method comprising:
forming a stack comprising alternately arranged sacrificial layers and insulating layers, the selective function layers and insulating layers having respective sidewalls;
recessing the sidewalls of the sacrificial layers or the sidewalls of the insulating layers to form recesses;
forming a plurality of discrete charge storage segments on the sidewalls of the sacrificial layers after the recessing;
forming a tunneling layer on the discrete charge storage segments;
forming a semiconductor layer on the tunneling layer;
removing the sacrificial layers to form a plurality of void spaces each between adjacent ones of the insulating layers, the void spaces exposing the discrete charge storage segments;
forming a blocking layer lining inner surfaces of the void spaces; and
forming a plurality of conductive layers in the void spaces.

18. The method according to claim 17, wherein recessing the sidewalls of the sacrificial layers or the sidewalls of the insulating layers comprises etching the sidewalls of the sacrificial layers to form the recesses;
wherein forming the discrete charge storage segments comprises selectively depositing the discrete charge storage segments on the recessed sidewalls of the sacrificial layers, and each of the discrete charge storage segments has an outer surface substantially even with the sidewalls of the insulating layers.

19. The method according to claim 17, wherein recessing the sidewalls of the sacrificial layers or the sidewalls of the insulating layers comprises etching the sidewalls of the sacrificial layers to form the recesses;
wherein forming the discrete charge storage segments comprises selectively depositing the discrete charge storage segments on the recessed sidewalls of the sacrificial layers;
wherein forming the tunneling layer comprises partially filling each of the recesses with the tunneling layer, thereby forming a remaining space in each of the recesses;
wherein forming the semiconductor layer comprises fully filling the remaining spaces with the semiconductor layer such that the semiconductor layer has corners in the remaining spaces.

20. The method according to claim 17, wherein recessing the sidewalls of the sacrificial layers or the sidewalls of the insulating layers comprises etching the sidewalls of the insulating layers to form the recesses, wherein each sacrificial layer has a protrusion protruding past the sidewalls of the insulating layers, and each of the protrusion has an exposed upper surface, an exposed lower surface and an exposed side surface;
wherein forming the discrete charge storage segments comprises forming the discrete charge storage segments covering the exposed upper surfaces, the exposed lower surfaces and the exposed side surfaces.
